(19) United States
(12) Patent Application Publication
(10) Pub. No.: US 2025/0327212 A1
(43) Pub. Date: Oct. 23, 2025

(54) A METHOD FOR HIGH YIELD NANOWIRE SYNTHESIS

(71) Applicant: UNIVERSITY OF LIMERICK, Limerick (IE)

(72) Inventors: Kevin M. RYAN, Oola (IE); Seamus KILIAN, Tobercurry (IE); Tadhg KENNEDY, Nenagh (IE)

(21) Appl. No.: 18/864,207

(22) PCT Filed: May 9, 2023
(86) PCT No.: PCT/EP2023/062323

§ 371 Date: Nov. 8, 2024

(30) Foreign Application Priority Data
May 9, 2022 (GB) 2206732.6

(51) Int. Cl. C30B 29/62; C30B 7/14; C30B 29/06; C30B 29/08

(52) U.S. Cl. CPC C30B 29/62; C30B 7/14; C30B 29/06; C30B 29/08

(57) ABSTRACT

A method for synthesizing a silicon and/or germanium nanowire(s) using a catalyst generated in situ is provided. The method provides high yield nanowire synthesis and comprises the steps of: combining a metal oxide, a reducing agent and a precursor in a reaction. The metal oxide and the reducing agent generate a metal oxide catalyst in situ in the reaction, and the catalyst reacts with the material from the precursor to synthesize nanowires.

### FIELD OF THE INVENTION

The current invention relates to a method for synthesizing silicon (Si) and/or germanium (Ge) nanowires. In particular, the invention relates to in situ generation of a catalyst in a method for synthesizing Si and/or Ge nanowires and nanowires produced by said method.

### BACKGROUND OF THE INVENTION

Nanowires are solid wires with a diameter in the order of nanometers and lengths of several micrometers. Nanowires from Group 14 of the periodic table are used in lithium-ion batteries as alloying anodes. Silicon, germanium, and tin are commonly used to fabricate nanowires. Silicon is the dominant material used and a wide range of Si nanowires are achievable though different growth methods. These semiconductor nanowires are often formed from a silicon precursor by etching of a solid, or through growth from a vapor or liquid phase.

Various methods for producing Si nanowires (NW) exist in the field. These include etching of a bulk silicon block (Hsu, C.-M., et al., Wafer-scale silicon nanopillars and nanocones by Langmuir-Blodgett assembly and etching. Applied Physics Letters, 2008. 93(13): p. 133109) synthesis of thin layer type by Chemical Vapour Deposition (CVD) (Westwater, J., et al., Growth of silicon nanowires via gold/silane vapor-liquid-solid reaction. Journal of Vacuum Science & Technology B: Microelectronics and Nanometer Structures Processing, Measurement, and Phenomena, 1997. 15(3): p. 554-557), vapor phase chemical synthesis over substrate (Mullane, E., et al., Synthesis of tin catalyzed silicon and germanium nanowires in a solvent-vapor system and optimization of the seed/nanowire interface for dual lithium cycling. Chemistry of Materials, 2013. 25(9): p. 1816-1822), gas phase synthesis over substrate (Burchak, O., et al., Scalable chemical synthesis of doped silicon nanowires for energy applications. Nanoscale, 2019. 11(46): p. 22504-22514) and synthesis in the liquid phase (Heitsch, A. T., et al., solution-liquid-solid (SLS) growth of silicon nanowires. Journal of the American Chemical Society, 2008. 130(16): p. 5436-543) or supercritical phase (Hanrath, T. and B. A. Korgel, Supercritical fluid-liquid-solid (SFLS) synthesis of Si and Ge nanowires seeded by colloidal metal nanocrystals. Advanced Materials, 2003. 15(5): p. 437-440), among others.

Etching of a bulk silicon block, synthesis of thin layer type by CVD and vapor phase chemical synthesis over substrate, comprise fabrication techniques whereby nanowires are formed at the surface of a usually planar substrate. These techniques are limited in their ability to produce large nanowire quantities (typically <1 mg) owing to the large surface areas otherwise required. The Si conversion efficiency, defined as the amount of Si contributing to nanowire with respect to the total Si used in the process, is also low at <1%.

In a more scaleable approach nanowires are grown on a sacrificial substrate (typically porous) from which nanowires can easily be removed after synthesis. This approach has been demonstrated by Pr S. B. Rananavare by using CaCO3 or glass wool as the sacrificial substrate (Chan, J. C., et al., Facile pyrolytic synthesis of silicon nanowires. Solid-state electronics, 2010. 54(10): p. 1185-1191). More recently, Burchak et al demonstrated this approach by attaching metal catalyst nanoparticles to NaCl (table salt) and retrieving the nanowires post synthesis by simply dissolving the NaCl sacrificial substrate in water allowing for nanowire yields of up to 500 mg (U.S. Pat. No. 8,207,521).

Fluid-based chemical synthesis of Si nanowires involves suspending the metal catalyst in the liquid (a solution) or supercritical phase of a suitable solvent and introducing a Si precursor. This approach has been performed by Prof B. A. Korgels research group, demonstrating its potential to achieve high nanowire yields of 5% and 60% in the liquid and supercritical phase, respectively. However, the expensive equipment and high pressures involved in the supercritical synthesis process limits its scalability and commercial viability.

Solution-based nanowire synthesis approaches can be performed at atmospheric pressure using a range of different metal catalyst nanoparticles including gold (Au), tin (Sn) and bismuth (Bi), which usually require the presence of capping agents to prevent agglomeration.

Lu et al generated a catalyst in-situ as an alternative to these prior art methods. This group used a one-step synthetic approach by injecting a Sn(II) complex as the precursor to form Sn NPs in-situ which subsequently catalyse the growth of Si or Ge NWs (Lu, X. and B. A. Korgel, A Single-Step Reaction for Silicon and Germanium Nanorods. Chemistry—A European Journal, 2014. 20(20): p. 5874-5879) The liquid Si precursor trisilane is commonly used, although others have been reported including cyclohexasilane, which can catalyze nanowire growth at temperatures as low as 200° C. (Lu, X., et al., Low temperature colloidal synthesis of silicon nanorods from isotetrasilane, neopentasilane, and cyclohexasilane. Chemistry of Materials, 2015. 27(17): p. 6053-6058).

These prior art strategies rely on the use of a metal catalyst, either in the form of a nanoparticle and thin-film to initialize NW growth. Both gas phase and fluid based chemical synthesis of Si nanowires rely on the use of metal nanoparticles as a catalyst, requiring a pre-synthesis preparation step that adds both cost and time to the overall nanowire fabrication process. Synthesising these NPs can be challenging. In fact, the synthesis of catalyst NPs was the biggest challenge facing the early development of scalable chemical synthesis of nanowire requiring new synthesis approaches.

Aside from the difficulties associated with using nanoparticle catalysts in a reproducible manner, the high costs associated with rare metals also limit their suitability as nanowire catalysts for battery applications where bulk nanowire quantities are needed. Moreover, these noble metal nanoparticles require storage and handling under inert conditions as the formation of an oxide layer can obstruct Si diffusion into the metal catalyst and impede nanowire growth. This further complicates the overall post-preparation process. In the case of gas phase synthesis approaches, further preparation is required as these nanoparticles also need to be uniformly attached to a sacrificial substrate.

Vapour-liquid-solid (VLS) growth is a bottom-up technique for the fabrication of nanowires. It involves the use of a metal catalyst that acts as a seed and is achieved by CVD or plasma enhanced CVD (PECVD) at a lower temperature.

The use of a catalyst oxide and reducing it in-situ during synthesis has previously been demonstrated to form Sn and In seeds to catalyse Si NWs, whereby H₂ gas was used to reduce SnO₂ and ITO films respectively. SiH4 gas was used as the Si precursor. (Manjunatha et al, Birth of silicon nanowires covered with protective insulating blanket. MRS Communications, 2017; Alet, P.-J., et al., In situ generation of indium catalysts to grow crystalline silicon nanowires at low temperature on ITO. Journal of Materials Chemistry, 2008; Linwei Yu, L., et al., Synthesis, morphology and compositional evolution of silicon nanowires directly grown on SnO2 substrates. Nanotechnology, 2008).

Linwei Yu et al, discusses discuss an in situ process for growing SiNW directly on tin oxide (SnO₂)/Corning glass (Cg) substrate in a plasma enhanced chemical vapor deposition (PECVD) system. In the method tin droplets are formed on the surface by H₂ plasma treatment on the SnO₂ layer. The tin droplets are then used as a catalyst for the growth of vapour-liquid-solid (VLS) growth of SiNWs in a silane (SiH₄) plasma.

Letian Dai et al, (Nanotechnology, vol. 29, no. 43, 2018) discusses a method for synthesizing SiNWs. The method comprises using tin dioxide radio frequency (RF) powder and H₂ plasma treatment followed by introduction of silane to allow NW synthesis.

Cheng ShiMin et al (Chemistry, December 2012, Vo. 55, No. 12:2573-2579) describes the growth of nanowires by CVD using in situ generated tin catalyst. In the method indium nanofilms as catalysts were vapour deposited on FTO and glass substrates by thermal evaporation of metal indium. SiH4 gas diluted in AR was introduced under atmospheric pressure into the deposition system to prepare the SiNWs.

US2011/0042642 describes a method for producing nanostructures on a metal oxide substrate. In this method metal aggregates are formed on the metal substrate by reducing plasma treatment. The substrate is then heated in the presence of a precursor gas to allow the vapour phase growth of nanostructures catalyzed by the metal aggregates.

Silane gas and H₂ gas are highly flammable with silane gas even having the tendency to auto ignite upon contact with air. The use of these gases therefore introduces a significant safety hazard. In addition, PECVD reactors require ultra-high vacuum conditions (˜10⁻⁶ mbar), limiting their scalability and increasing the energy needed during the synthesis process.

The current invention alleviates one or more of the problems of the prior art by providing a method comprising an in situ generated metal oxide catalyst. The method is safe, low in cost and scalable.

### SUMMARY OF THE INVENTION

The current invention provides scalable, high yield, synthesis of silicon and/or germanium nanowire(s). The method is a single reaction by concomitant reduction of a metal oxide, e.g., ZnO, in situ using a reducing agent, such as lithium borohydride (LiBH4) to form a catalyst, e.g., ZN catalyst, and the formation of nanowires in the presence of an appropriate precursor, e.g., phenylsilane as a silicon precursor.

In contrast to prior art methods, the current invention allows the growth of nanowires in the liquid phase typically using liquid precursors.

The metal oxide is reduced by the reducing agent to form a metal catalyst or seed. In the presence of the precursor, which decomposes to release silicon or germanium depending on the precursor, this catalyst absorbs the silicon or germanium. This leads to growth of a nanowire from the catalyst. These actions occur concurrently.

Notably, by adding the reducing agent to the reaction after the precursor, the reduction sites immediately begin catalysing NW growth. This removes the need to control the rate at which the metal oxide is reduced.

In addition to single nanowires arising from the metal catalyst, a significant quantity of hyper branched structures is yielded using the approach of the current invention, where either multiple wires are seeded from a single seed, or where branching is in a single nanowire structure cause by the fusion of the reduction sites.

The use of the metal oxide to generate the catalyst in situ eliminates many of the above noted issues associated with the prior art methods. Metal oxides are generally easier to synthesise, less expensive and do not require storage under inert conditions. This greatly simplifies the overall post-synthesis preparation.

It will be appreciated that the method of the invention can be applied to any wet chemical nanowire synthesis method or reaction.

An aspect of the current invention provides a method for synthesizing a silicon and/or germanium nanowire(s), the method comprising the steps of combining a metal oxide, a reducing agent, and a silicon and/or germanium precursor in a reaction to synthesize the nanowires.

The metal oxide and reducing agent generate a metal catalyst and wherein the metal catalyst reacts with material from the precursor to synthesise nanowires.

Typically, the method comprises combining or adding the metal oxide, the reducing agent and precursor to the reaction simultaneously. Alternatively, the method comprises combining a metal oxide and a precursor to the reaction and subsequently adding the reducing agent to the reaction.

The method may be solution-based method.

In an embodiment, the metal oxide is any transition metal oxide. It may be selected from the group comprising zinc oxide, iron oxide, magnesium oxide, scandium oxide, titanium oxide, manganese oxide, vanadium oxide, chromium oxide, cobalt oxide, and nickel oxide. Preferably, the metal oxide is zinc oxide (ZnO).

The metal oxide may be a solid. It may be a pellet or a powder. In an embodiment, the metal oxide is a thin layer on an inactive (i.e., does not react with precursor e.g., graphite) substrate.

The precursor may be a liquid or a gas.

In an embodiment, the reducing agent is selected from the group comprising lithium aluminium hydride, sodium borohydride, lithium, lithium tetrahydridoaluminate, lithium tri-tert-butoxyaluminum hydride and lithium triethylborohydride. Preferably, the reducing agent is lithium borohydride (LiBH4).

In an embodiment, the precursor is a silicon precursor, and the metal catalyst reacts with the silicon from the precursor to synthesise nanowires. In an embodiment, the silicon precursor comprises silane. Preferably, the precursor is selected from phenylsilane, diphenylsilane, silane, tetraphenylsilane, halosilanes including chlorosilane, trimethylsilane, tetramethylsilane, hexachlorodisilane and silicon iodide.

In an embodiment, the precursor is a germanium precursor, and the metal catalyst reacts with the germanium from the precursor to synthesis nanowires. In an embodiment, the germanium precursor may be selected from the group comprising phenylgermane, diphenylgermane, triphenylgermane and GeX4, (X=Cl, Br, I).

It will be appreciated that when the product is an SiGe nanowire, a mix of appropriate precursors is used. This may be one or more of the silicon precursors disclosed herein and one or more of the germanium precursors disclosed here.

In an embodiment, the reaction is one suitable for gas, liquid or fluid phase synthesis of nanowires, typically liquid or fluid phase and typically with metal oxide in pellet, powder or thin-film form. Typically, the reaction comprises a refluxing solvent, but it will be appreciated that any suitable solvent can be used. In an embodiment, the reaction comprises a high boiling point solvent which is heated to a reaction temperature greater or equal to 380° C., to produce a refluxing solvent. Preferably, the reaction temperature is from 380° C. to 470° C.

In a preferred embodiment, the solvent is selected from squalane, octadecene and ethylene glycol.

The invention provides a method for synthesizing a silicon and/or germanium nanowire comprising in situ generation of a metal catalyst, said method comprising,
heating a high boiling point solvent comprising a metal oxide to produce a refluxing solvent,
adding a silicon and/or germanium precursor
adding a reducing agent to provide a mixture, and
reacting the mixture to obtain growth of silicon nanowires and/or germanium nanowires.

The high boiling point solvent is heated to a temperature of from 370° C. to 490° C., typically around 470° C., to produce a refluxing solvent.

Typically, the method of the invention is conducted in a single vessel or chamber. This may be a flask. It may be a suitable refluxing apparatus.

Typically, the method of the invention comprises a step of providing a constant flow of inert argon to control the production of said nanowires.

Typically, the method of the invention is carried out at atmospheric pressure.

Typically, the method of the invention is carried out in an environment or system without no moisture or air.

An aspect of the current invention provides Si nanowire(s) produced by the method of the invention.

An aspect of the current invention provides a Ge nanowire(s) produced by the method of the invention.

An aspect of the current invention provides an SiGe nanowire(s) produced by the method of the invention.

Typically, the nanowire structure comprises branching. This may be branching of a single nanowire.

Preferably, the nanowire comprises a mean diameter of from 60 nm to 90 nm. The form of the metal oxide used in the method influences the resulting diameter.

### Definitions and General Preferences

Where used herein and unless specifically indicated otherwise, the following terms are intended to have the following meanings in addition to any broader (or narrower) meanings the terms might enjoy in the art:

Unless otherwise required by context, the use herein of the singular is to be read to include the plural and vice versa. The term “a” or “an” used in relation to an entity is to be read to refer to one or more of that entity. As such, the terms “a” (or “an”), “one or more,” and “at least one” are used interchangeably herein.

As used herein, the term “comprise,” or variations thereof such as “comprises” or “comprising,” are to be read to indicate the inclusion of any recited integer (e.g., a feature, element, characteristic, property, method/process step or limitation) or group of integers (e.g., features, element, characteristics, properties, method/process steps or limitations) but not the exclusion of any other integer or group of integers. Thus, as used herein the term “comprising” is inclusive or open-ended and does not exclude additional, unrecited integers or method/process steps.

When used herein the term “Lithium borohydride” (LiBH4) is a borohydride and known in organic synthesis as a reducing agent for esters.

When used herein the term “silicon precursor” is a material or compound that participates in a reaction to produce silicon. Silicon precursors are generally high purity gas or liquid materials. Preferably, the precursor is a liquid.

When used herein the term “reducing agent” is an element or compound that loses or donates an electron to an electron recipient (called oxidising agent or oxidant) in a chemical reaction. The reducing agent undergoes oxidation. The oxidising agent is reduced. It may be any reducing agent suitable for and capable of reducing a metal oxide.

When used herein the term “volume based chemical synthesis” refers to a method involving suspending the metal catalyst in the liquid or supercritical phase of a suitable solvent and introducing a precursor, e.g., Si precursor.

When used herein the term “solution-based synthesis” refers to the growth of nanowires in a liquid media. For example, the precursor and the seed are in liquid media. The precursor is typically in solution.

When used herein the term “sacrificial substrate based chemical synthesis” refers to a method in which nanowires are grown on a porous sacrificial substrate from the thermal breakdown of precursors and from which nanowires can easily be removed after synthesis.

It will be appreciated the term “chamber” should be afforded a broad interpretation in the context of the present invention and can be of any dimension and size to allow the method of producing the nanowires according to the invention. It can include a flask, such as a round bottom flask.

“squalene” (C₃₀H₆₂) is a hydrocarbon derived by hydrogenation of squalene. It is 2,6,10,15,19,23-hexamethyltetracosane.

“Phenylsilane” (Ps), also known as silylbenzene, a colourless liquid, is one of the simplest organosilanes with the formula C₆H₅SiH₃.

The term “reaction” when used herein is the nucleation and growth of a nanowire from a substrate made possible by the presence of a precursor and reducing agent and metal oxide as a sacrificial catalyst It may be any wet chemical system or environment suitable for this nucleation and growth of nanowires. Such systems are known in the art and may include but are not limited to systems for pyrolytic synthesis and volume-based synthesis of nanowires. It may be a lab-based system.

The term “solution-liquid-solid (SLS)” when used herein is defined as the bottom-up growth of nanowires using a liquid catalyst in a liquid media. In this type of method, the liquid form of the catalyst occurs in situ. For example, in the context of this invention, the reducing agent reduces the metal oxide which is a liquid during catalysis. Examples are provided in Andrew T Heitsch, et al., (Solution Liquid Solid (SLS) growth of silicon nanowires, J.Am. Chem. Soc. 2008, 130, 16, 5436-5437).

The term “refluxing” when used herein refers to a technique of heating a chemical reaction for an amount of time, while continuously cooling the vapour produced by heating back into liquid form. A “refluxing solvent” is one that is undergoing reflux. Generally, the solvent is heated to its boiling point. This technique facilitates heating without significant loss of the solvent. “Refluxing conditions” are the conditions or parameters that allow this process to take place.

### BRIEF DESCRIPTION OF THE FIGURES

The invention will be more clearly understood from the following description of an embodiment thereof, given by way of example only, with reference to the following Figures in which;

FIG. 1: Schematic illustration of solvent vapour growth system used for synthesising Si NWs using (a). ZnO pellets and (b) ZnO powder with corresponding 2-step growth mechanism. In both cases, the reducing agent LiBH₄ reduces the ZnO to Zn which in the presence of phenylsilane begin catalysing Si NW growth.

FIG. 2: SEM images of ZnO pellet surface including prior to synthesis (a), After blank reaction and exposure to LiBH₄ show evidence of Zn islands forming across the surface (b) and Si NW growth due to the presence of phenylsilane (c). Top right inset showing higher resolution SEM imaging of Zn islands and Si NW growth. Bottom right inset showing optical photos of the pellets highlight the transition in colour occurring between at each respective stage from white (a) to metallic grey (b) to an orange/yellow colour (c). (d) XRD of the pellet before synthesis, after blank reaction and after NW growth is shown in (i), (ii) and (iii) respectively. XRD reference patterns for ZnO, Zn and Si are shown in d (iv).

FIG. 3: (a) SEM image of Si NW growth on ZnO pellet surface. Inset shows TEM image of wire-seed interface. (b) Cross section of ZnO pellet after reaction, showing that NW growth is restricted to surface. Inset showing ZnO pellet after HCl clean.

FIG. 4: Size distribution for NW diameters for ZnO pellet (a) and ZnO powder (b).

FIG. 5: (a) SEM image of ZnO powder used for the in-solution synthesis of Si NWs. Inset (i) BF-TEM image showing variation in ZnO particle size and morphology (b) SEM image of untreated Zn—Si NW powder. Inset (i) SEM image of Zn—Si NW and ZnO particles in untreated powder. (d) XRD of powder retrieved after reaction showing peaks for Si, Zn and ZnO. Inset (i) Corresponding quantitative XRD showing the powders compositional percentage of Zn, Si and ZnO. (e) (i) STEM of Zn—Si NW with corresponding elemental of Zn (ii) and Si (iii) and O (iv).

FIG. 6: BF-TEM images of observed NW structures including single Zn—Si interface NW with frayed endings (a) and Zn seeds Si NW interfaces (b). Top right insets in a and b show corresponding illustrations of the observed NW structures. (c) STEM image (i) of Zn seed featuring three Si NW interfaces and corresponding EDX elemental mapping for Zn (ii) and Si (iii) and O (iv). (d) TEM image showing three individual NWs with partially fused Zn seeds. (e) TEM showing of frayed NW ending consisting of NWs with smaller diameters. (f) TEM images of fused NWs which subsequently continues growth.

FIG. 7: (a) STEM image of partially fused Zn NPs. (b) TEM image of ZnO particle after exposure in to LiBH₄ where Zn reduction sites are indicated by green arrows. (c) Higher resolution imaging of a reduction site indicated by red square in (b). (d) STEM imaging of the same ZnO particle with corresponding EDX line-scan indicated by blue arrow. TEM image of partially reduced ZnO particle showing formation of Zn droplet.

FIG. 8: (a) XRD of NW powder after HCL clean showing Si peaks at 28°, 47° and 56°. (b) BF-TEM of NW cluster after synthesis showing absence of Zn seeds. (c) XPS of NW powder before HCl clean (red) and after (brown) showing that Li by-products are removed. (d) Optical photograph of NW powder retrieved after synthesis and cleaning step.

### DETAILED DESCRIPTION OF THE INVENTION

All publications, patents, patent applications and other references mentioned herein are hereby incorporated by reference in their entireties for all purposes as if each individual publication, patent or patent application were specifically and individually indicated to be incorporated by reference and the content thereof recited in full.

The current method provides a method of synthesizing nanowires using a catalyst prepared in situ. One embodiment can use a solution liquid solid (SLS) approach. The material used to form the nanowire may be silicon, germanium, or a silicon germanium alloy. Thus, the nanowires produced may be a silicon nanowire and/or germanium nanowire.

It will be appreciated that the method of the invention may lend itself to be used with reaction that made possible by the presence of a precursor and reducing agent. It may be any SLS approach.

The method comprises combining a metal oxide, a reducing agent, and a suitable precursor in a reaction system. The combination is in liquid media. It will be appreciated that any suitable liquid may be used depending on the method of synthesis. The reaction typically comprises a solvent. The type of solvent depends on the approach used. One example is a refluxing solvent.

The method generates a metal oxide catalyst in situ while forming nanowires. The metal oxide and precursor may be added first, and the reducing agent added subsequently.

The metal oxide and reducing agent generates a metal catalyst or seed in situ. The suitable material is released from the precursor; this may be silicon or germanium depending on the precursor used. The metal catalyst reacts with the substrate to synthesise nanowires. For example, the silicon precursor decomposes to release silicon and the silicon reacts with the metal seed to form silicon nanowires.

In a typical reaction system, the weight ratio for the metal oxide: reducing agent: precursor is 5:5:66. However, it will be appreciated that other ranges are possible. The ratio may be from 1 to 10:1 to 10:50 to 100.

Typically, the reaction proceeds for a time suitable to grow the nanowires, for example, 2 hours, or 1.5 hours.

Typically, the reaction has a reaction temperature of about 470° C. The reaction temperature maybe one at or over 370° C., preferably from 370° C. to 490° C. it may be at or above, 395° C., 400° C., 405° C., 410° C., 415° C., 420° C., 425° C., 430° C., 435° C., 440° C., 445° C., 450° C., 455° C., 460° C., 465° C., 470° C., 475° C., 480° C. or 485° C.

It will be appreciated that the method may comprise multiple rounds of injections or additions of components. If replenished, an amount of the metal oxide can be added, followed by or in combination with the precursor and then the reducing agent. This can be repeated one or more times. If the reagents are not replenished, the reaction is cooled.

The produced silicon and/or germanium nanowires can then be removed from the reaction system. This can be by any standard and known technique.

Notably, in an embodiment, the method of the invention has a conversion efficiency, i.e., how much silicon in the precursor is converted to silicon in the nanowires, of from about 20% to about 80%, typically about 25% to about 70%, about 30% to about 60%, about 50%, about 40%, about 35%, typically from about 25% to about 31%.

The metal oxide may be in the form of a pellet or a powder, or thin layer on a substrate Notably, if a metal oxide pellet is used in the method of the invention can be removed from the reaction system and treated e.g., soaked in toluene overnight, to remove any organic contaminants. Suitable methods are known in the art. The pellets can then be washed, e.g., in IPA and dried. The pellets are reusable.

The nanowires are then removed. This can be by any standard and known technique, such as sonication in acidified IPA. It will be appreciated that any suitable acid can be used for removal. These include but are not limited to nitric acid, sulfuric acid, acetic acid and phosphonic acid.

In the case of the metal oxide being a powder, the nanowire powder is removed from the reaction and washed, e.g., by centrifugation. This can be in toluene, one or more times, typically three times, to remove the solvent and other organic by-products. The supernatant is removed and sonicated in acidic solution to remove the seeds and the residue metal oxide. The NW powder can then be extracted by centrifugation and removal of the acidic supernatant. This can be one or more times, typically two or more times. The purified NW powder is then removed and allowed to dry, typically at 90° C. overnight, e.g., 12 hours.

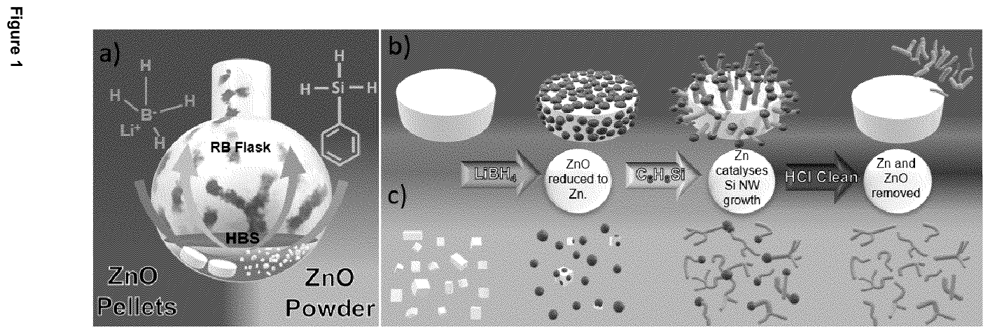

An overview of one embodiment of the method of the invention is shown in FIG. 1. Broadly, the method of this embodiment uses a reaction system comprising a refluxing solvent. The refluxing solvent is providing by heating a high boiling point solvent to produce a refluxing solvent. The solvent in this example is squalane.

The metal oxide used may be in the form of a pellet (Figure B) or a powder (FIG. 1C).

When the pellet is added to the high boiling point solvent, it is heated to the reaction temperature or 470° C.

When the metal oxide is a powder, the powder is dispersed in the high boiling point solvent, and it is heated to reflux.

For both formulations of the metal oxide, the reaction temperature is increased to around 470° C. and an amount of a Si precursor, in this instance PS, is added to the reaction. An amount of a reducing agent, in this instance LiBH₄, is then added to the reaction. The reaction is allowed to proceed for a time suitable to grow nanowires, for example in this instance 2 hours for pyrolysis and 1.5 hours for volume-based approach.

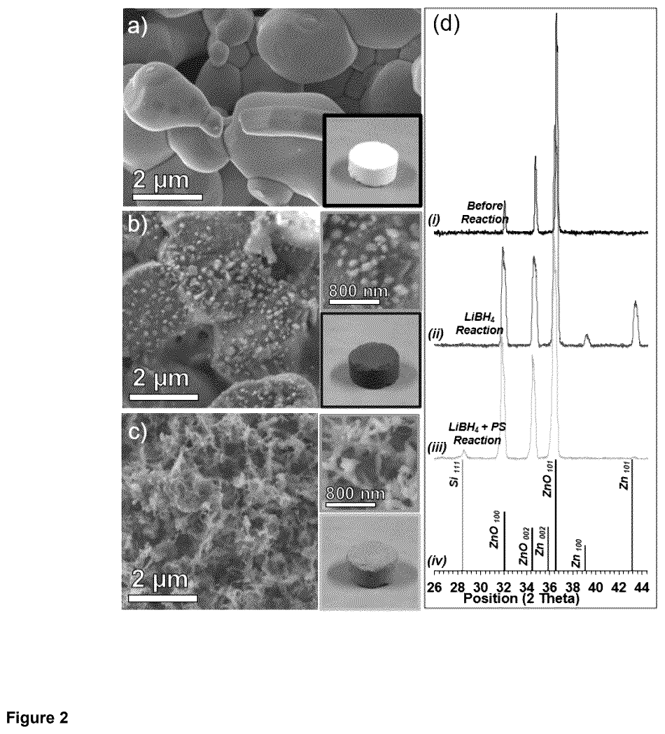

When the metal oxide is in the form of a pellet, in the reaction, the metal oxide ZnO is reduced by the reducing agent LiBH₄. This forms metallic Zn at the pellets surface. In the presence of PS, these Zn islands (or seeds) begin absorbing silicon upon formation from the surrounding solution giving rise to the SLS growth of crystalline silicon nanowires. This is shown in FIG. 2B. The nanowire growth is restricted to the pellet surface. This allows for the pellet to be reused by removing the silicon nanowires.

After this point, the reaction may be terminated or continued by replenishing the ZnO, PS and LiBH₄. If terminated, the reaction is cooled. If replenished, an amount of the metal oxide can be added, followed by the Si precursor and then the reducing agent. This can be repeated one or more times.

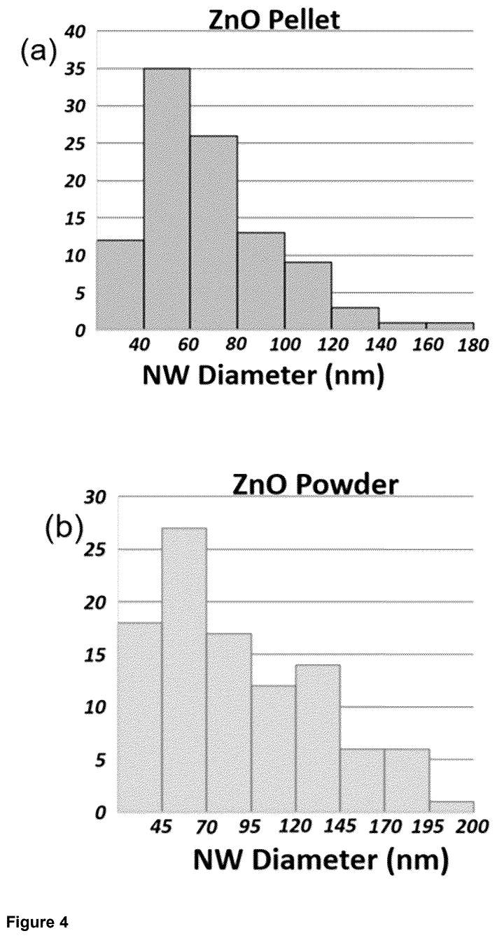

Generating the catalyst using ZnO in powder form results in a mean NW diameter of around 88 nm (see FIG. 4b for size distribution). This may be from 80 to 95 nm, preferably 82 nm, 84 nm, 86 nm, 88 nm, 90 nm, 92 nm, or 94 nm. The standard deviation is 45.22.

The nanowires catalysed from the ZnO pellets were found to have a mean diameter of 68 nm (FIG. 4a). This may be from 60 to 75 nm, preferably 62 nm, 64 nm, 66 nm, 68 nm, 70 nm, 72 nm, or 74 nm. The standard deviation is 28.58.

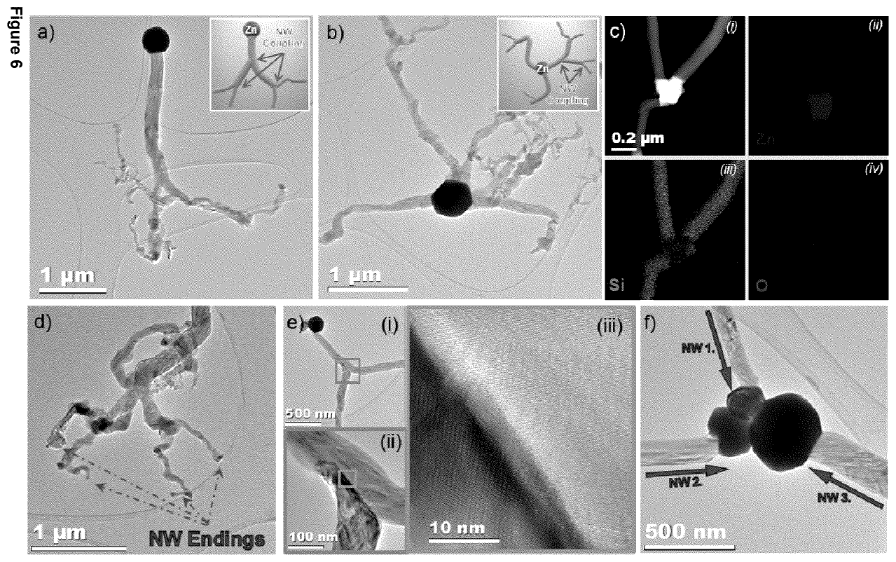

The NWs synthesised using the in-solution approach were categorized into two different types of structures. The first type of NW structure, shown in FIG. 6a, featured a single Zn—NW interface. The other type of structure, seen in FIG. 6b, featured a Zn seed with multiple NW interfaces. NW coupling was observed for both structures, whereby the NWs connected to the Zn seed fork out into NWs with smaller diameters (insets 6a and b). The coupling of NWs during growth as well as Zn seeds featuring multiple NW interfaces may be explained by seed fusion occurring during synthesis.

The method of the invention avoids many of the disadvantages of the methods of the prior art.

In contrast to prior art methods, the method of the invention does not require the use of metal nanoparticles. This greatly simplifies the overall post-synthesis preparation.

Notably, there is no pre-synthesis catalyst preparation in the method of the invention. Most methods for producing silicon nanowires require a pre nanowire synthesis step to form the metal catalyst in the form of nanoparticles or a thin film. In the method of the invention, the catalyst is formed in-situ by reducing a metal oxide during synthesis. This lowers both time and costs associated with the overall nanowire fabrication process.

The materials used in the method of the current invention are inexpensive. Compared to commonly used catalysts used for synthesis approaches including Au and Bi, Zn is significantly cheaper and of greater abundance. This cost advantage is further enhanced by using ZnO as the catalyst precursor. ZnO occurs naturally as the mineral zincite and is a particularly appealing oxide to generate the nanowire catalyst in-situ as it is cheap and readily available in both bulk and powder form, making it suitable for producing large nanowire quantities. Furthermore, the use of ZnO greatly simplifies any necessary post synthesis purification steps owing to the readiness of both Zn and ZnO to dissolve in dilute acid solutions.

The approach of the current invention for the in-situ generation of the catalyst can be used in gas, liquid and fluid-based synthesis approaches using the metal oxide in pellet or powder form. Upon addition of the reducing agent such as LiBH₄ to the reaction, the reduction sites that form at the surface of the bulk ZnO catalyse silicon nanowire growth in the presence of phenylsilane.

The method of the invention is scalable and allows for high nanowires yields. Allowing for Si nanowire yields between 200 and 400 mg in a 100 ml reactor and a chemical efficiency between 20 and 30% when using ZnO powder, the method of the invention can produce bulk nanowire quantities.

The system can be kept under control using standard techniques of a constant flow or inert argon gas through the system, coupled with a water condenser attached to the system.

The entire method is conducted at atmospheric pressure.

The invention will now be described with reference to specific Examples. These are merely exemplary and for illustrative purposes only: they are not intended to be limiting in any way to the scope of the monopoly claimed or to the invention described. These examples constitute the best mode currently contemplated for practicing the invention.

### EXAMPLES

### Methodology and Results

The reaction was carried out in a reactor setup described in previous works by Ryan et al (EP2261402).

This glassware-based nanowire synthesis approach, shown in FIG. 1a, involves heating a high-boiling point solvent to produce a refluxing solvent. The liquid Si precursor phenylsilane is injected into the reaction at a temperature above its reaction temperature.

For pellet-based synthesis, depicted in FIG. 1a, 7 mL of squalane are added to a custom-made pyrex round-bottomed flask along with ZnO pellets which are fully submerged in squalane. The flask was attached to a water-cooled condenser and placed inside a 3-zone furnace. The condenser was connected to a Schlenk line with a vacuum and Ar line. The flask was placed under vacuum and heated to 125° C. for 30 minutes ensuring that all moisture was removed from the system. After this the system was purged with Ar and the furnace was ramped up to the reaction temperature of 470° C. 0.75 mL of the precursor phenylsilane (PS) and 0.05 mL of 2 M LiBH₄ in THF are prepared in an Ar-filled glovebox. The PS was added to the reaction first followed by LiBH₄ both of which are injected through the septum cap on the condenser. The reaction was allowed to proceed for 2 hours after which it was terminated by turning off the furnace and opening it allowing the system to cool down naturally. The pellets were removed from the flask and soaked in toluene overnight to remove any organic contaminants. The pellets are then transferred then sonicated in acidified IPA to remove the NWs attached to its surface. To prepare the pellets use in the next reaction, the pellets are washed with IPA, placed in an oven at 90° C. and allowed to dry overnight.

FIG. 2(a-c) of the pellets surface captures the different stages during the growth process, whereby the initially pristine ZnO (FIG. 2a) is reduced by LiBH₄ to from metallic Zn at the pellets surface. This results in the formation of Zn islands across the surface as shown in FIG. 2b, which was produced by injecting LiBH₄ into the flask without the addition of PS. The formation of Zn at the pellets surface is also apparent from the colour change shown in the insets of FIG. 2a and b, as the initially white ZnO pellets turn into a metallic grey colour upon exposure to LiBH₄ in the blank reaction. In the presence of PS, these Zn islands begin absorbing Si upon formation from the surrounding solution giving rise to the SLS growth of crystalline Si NWs FIG. 2c. The optical photograph after the reaction in the inset in FIG. 2c shows that the pellets are dark yellow in colour, characteristic of nanostructured Si. XRD analysis of the pellet prior to the reaction, after a reaction using just LiBH₄, and using both LiBH₄ and PS to produce Si NWs are shown in FIG. 2d (i), (ii) and (iii) respectively. XRD of the pellet before synthesis (FIG. 2d (i)) correspond to pristine ZnO (FIG. 2d (iv)). After exposure to LiBH₄, the resultant XRD pattern seen in FIG. 2d (ii) features the initially observed peaks for ZnO as well peaks at 39° and 43° which are characteristic of metallic Zn. The <002>Zn peak at 36° is overshadowed by the ZnO <101>peak occurring at a similar angle. Subjecting the pellet to both LiBH₄ and PS to achieve NW growth yields the main Si <111>diffraction peak at 28.4° as shown in FIG. 2d (iii). While the main <101>diffraction peak of metallic Zn is visible at 43.2, its intensity relative to the ZnO peaks is significantly less compared to Zn peaks detected by the pellet exposed to LiBH₄ in the blank reaction. The previously observed Zn peak at 43° is also no longer visible as their intensities are below the detectable limit.

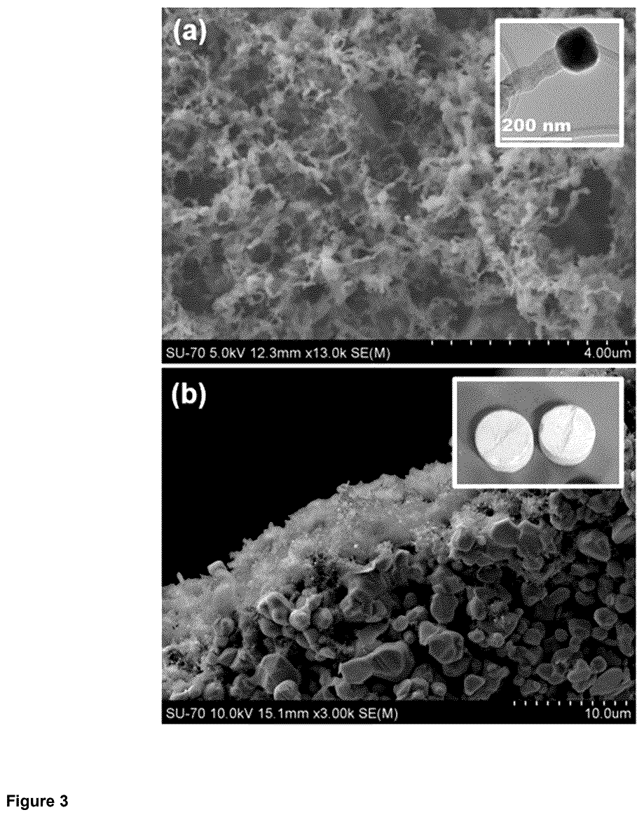

SEM imaging of the pellets surface (FIG. 2a) show that the ZnO pellets consist of compressed microparticles, giving the pellets a degree of porosity. However, cross-sectional SEM imaging of the pellet after synthesis, which was performed by splitting the pellet perpendicularly to its surface, shows that NW growth is restricted to the pellets surface with the underlying ZnO remaining intact (FIG. 3). This allows for the pellets to be reused multiple times by removing the Si NWs via sonication in acidified IPA (0.5 M HCl). This causes the NWs to rapidly detach from the pellet as the underlying ZnO is dissolved. Following this cleaning step, the pellet regains its initially pristine white appearance (FIG. 3b inset (i)). The NWs catalysed from the ZnO pellets where found to have a mean diameter of 68 nm (FIG. 4a)

Using the powder-based synthesis approach, as illustrated in FIG. 1c, 50 mg of ZnO powder was dispersed in 7 mL of squalane via sonication for 30 minutes and subsequently added to the pyrex round-bottomed flask. The flask was attached to a water-cooled condenser and placed inside a 3-zone furnace. The condenser was connected to a Schlenk line with a vacuum line and Ar line. The flask was placed under vacuum and heated to 125° C. for 30 minutes ensuring that all moisture was removed. The system is then purged with Ar and the furnace is ramped up to the reaction temperature between 390 and 470° C. 0.75 mL of the precursor phenylsilane PS and 0.05 mL of 2 M LiBH₄ in THF are prepared in an Ar-filled glovebox. The PS was added to the reaction first followed by the LiBH₄ both of which are injected through the septum cap on the condenser. The reaction was allowed to proceed for 1 hour 30 minutes. After this point, the reaction may be terminated or continued by replenishing the ZnO, PS and LiBH₄. To do so, 30 mg of ZnO powder suspended it in 1 mL of squalane was injected via the septum cap. The reaction was left for a few minutes to ensure the temperature stabilises. 0.75 mL of PS is then injected and allowed to reflux for some time before injecting 0.05 mL LiBH₄. The reaction is allowed to proceed for another 1 hour 30 minutes. This process was repeated multiple times to increase NW yield per reaction. The reaction was terminated by turning off the furnace and opening it to allow the system to cool down to room temperature. The NW powder was removed from the flask and washed by centrifuging it in toluene 3 times to remove the squalane and other organic by-products. The supernatant was removed and IPA containing 0.5M HCL was added to the powder which was sonicated for 10 minutes to remove both the Zn seeds and residue ZnO. The NW powder is extracted by centrifugation at 500 RPM and removing the acidic supernatant. This was repeat two more times using normal IPA to ensure that all dissolved ZnCl₂ was removed. The purified NW powder was then removed allowed to dry in an oven at 90° C. overnight.

Generating the NW catalyst using ZnO in powder form resulted in a mean NW of 88 nm (see FIG. 4b for size distribution).

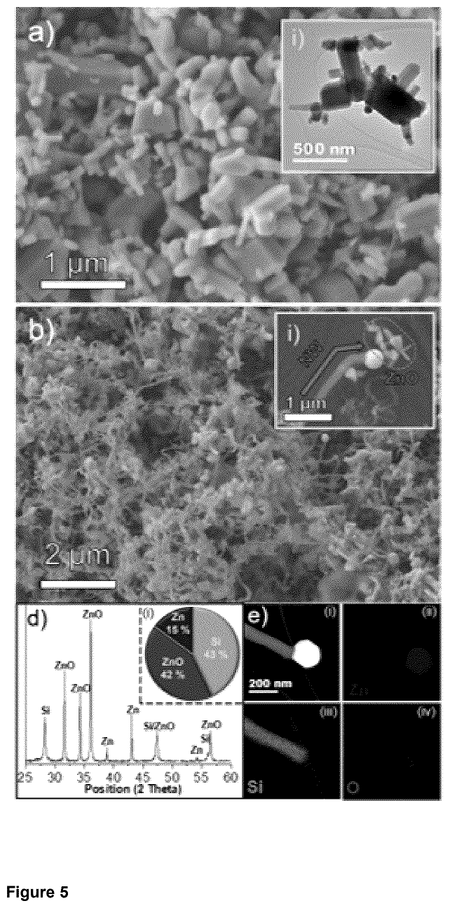

SEM and TEM imaging of the ZnO powder is presented in FIG. 5a and inset (i) respectively show that the individual particle sizes and shapes vary substantially. SEM images of the product after the reaction seen in FIG. 5b show that Si NWs are present in high yield alongside some unreacted ZnO (FIG. 5b inset (i)). XRD of the powder after synthesis (FIG. 5d) produces peaks characteristic of Si, Zn and ZnO further highlighting that a certain amount of unreacted ZnO remains in the powder after synthesis. Quantitative XRD analysis (FIG. 5d inset (i)) was used to estimate the powders relative atomic composition of Si, Zn and ZnO which was found to be 43% Si, 15% Zn and 42% ZnO. The high proportion of ZnO is due to the fact that excess quantities are used to ensure that all phenylsilane is consumed resulting in a high Si conversion efficiency. While the ZnO powder is dispersed throughout the HBS prior to synthesis via sonication, some of this powder was found to settle at the bottom of the RB flask during synthesis. This settled ZnO forms a layer which limits the ability of lower lying ZnO particles to participate in the growth process as the diffusion of PS and LiBH₄ is restricted.

STEM imaging and corresponding EDX elemental mapping of the NW-seed interface are shown in FIG. 5e. The elemental mapping show that the Zn seed itself contains negligible amounts of Si (FIG. 5e (i)), highlighting the nature of Zn as a type B catalyst. This class of NW catalysts include metals such as Zn, Sn and In and are characterised by having a Si solubility of <1% causing the seeds to supersaturate at very low Si concentrations. The amount of Zn incorporated into the NW itself was below the EDX detection limit, suggesting the formation of pure phase Si. EDX elemental mapping for O in FIG. 5e (iv) shows that while some O counts are picked up around the Zn seeds due to the formation of an oxide layer, the relatively low counts suggest that the seed remains largely in the form of metallic Zn after the reaction.

The NWs synthesised using the in-solution approach were categorized into two different types of structures. The first type of NW structure, shown in FIG. 6a, featured a single Zn—NW interface. The other type of structure, seen in FIG. 6b, featured a Zn seed with multiple NW interfaces. NW coupling was observed for both structures, whereby the NWs connected to the Zn seed fork out into NWs with smaller diameters (insets 6a and b). The coupling of NWs during growth as well as Zn seeds featuring multiple NW interfaces may be explained by seed fusion occurring during synthesis. EDX elemental mapping of a Zn seed attached to multiple NWs in FIG. 6 show its compositional properties are similar to those observed for the single Zn—Si NW in FIG. 6e (i-iii), such that very little Si is evident within the Zn seed. NW coupling resulted in the formation of frayed endings comprised of NWs with smaller diameters as shown in FIG. 6d. The coupling of two larger NWs which continues growth as a single NW upon merging is shown in FIG. 6e. Higher resolution TEM imaging of the point of convergence is shown in FIG. 6e (i) and (ii). Focusing on the zone axis of one of the coupled NWs produces a noticeable change in image contrast as the crystal orientations of the NWs are different. FIG. 6e (i) & (ii) shows that the two NWs having merged into a single NW continues to grow with two parallel crystal orientations for approximately 200 nm. Evidence of seed fusion taking place was found in the form of partially fused Zn seeds as seen in FIG. 4f, where each of the distinct Zn seeds is connected to a different NW. NW coupling may occur upon the fusion of two or more seeds resulting in the growth of a single NW provided PS is still present in the system.

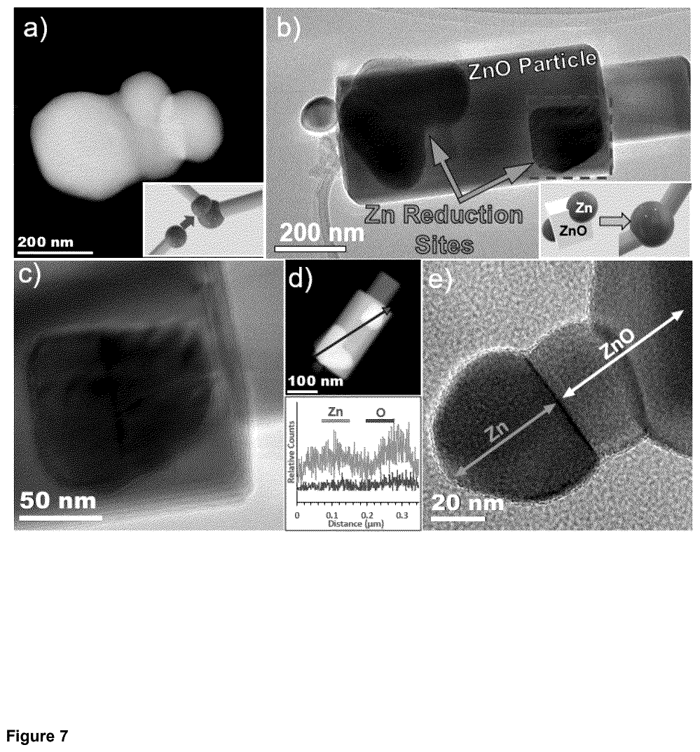

Evidence of two fusion mechanisms is observed. The first involves the fusion of Zn seeds which come into contact during synthesis after separately catalysing NWs. To verify this fusion process occurring between two separate NW seeds, Zn NPs where dispersed in squalane and subjected to the same reaction conditions (excluding phenylsilane). Similar to the partially fused seeds observed during NW growth, STEM imaging of the Zn NPs after the reaction also show partially fused NPs (FIG. 7a). Zn-seeded Si NWs directly attached to ZnO particles were not observed. This suggests that the initial reduction process and NW growth occurs within a very short time frame.

To capture the initial stages of the reduction process, the ZnO powder was exposed to a low concentration of LiBH₄ in a reaction containing no phenylsilane. Subsequent TEM analysis of the ZnO particles (FIG. 7b-e) show evidence of Zn reduction sites forming on the ZnO particles surface. STEM imaging of the particle (FIG. 7d) shows a clear change in contrast between the indicated Zn reduction sites and the ZnO particle. A corresponding EDX line-scan (indicated by blue arrow) shows an increase in the counts for Zn relative to O across the two reduction sites, indicating the formation of metallic Zn. The side view of a Zn reduction site (FIG. 7e) shows the initial formation of seed-like droplets. Previous reports have shown that the reduction of metal oxide nanoparticles commences with the formation of multiple reduction sites across the particle which increase in size until complete reduction of the oxide particle has occurred. These Zn reduction sites may act as initial nucleation points for NWs by supersaturating before the remaining ZnO particle is reduced. During this reduction process, the NWs may begin coupling as seed fusion occurs between the individual reduction sites. While both the fusion of individual NW seed and reduction sites are believed to contribute to the coupling of NWs, the latter mechanism may be expected to occur earlier during NW growth and is the dominant source of NW coupling giving rise to the frayed ending observed on most NWs. Using ZnO powder to generate the catalyst in-situ allowed for a Si conversion efficiency between 24.5 and 31.5%.

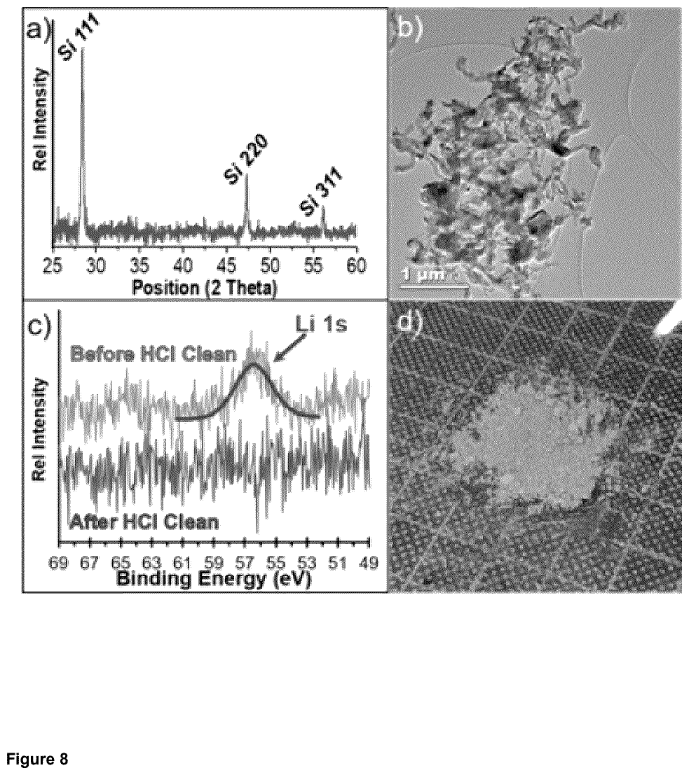

Owing to the readiness of both ZnO and Zn to dissolve in a dilute acidic solution, a purification step is introduced after synthesis to remove both the ZnO and Zn seeds by sonicating the powder using acidified IPA (0.5 M HCl) for 10 minutes. XRD analysis of the powder after this purification step shown in FIG. 8a produces peaks at 28°, 47° and 56°, characteristic of crystalline Si while the previously observed peaks for ZnO and Zn (FIG. 5d) are no longer visible. TEM analysis of the purified NW powder showing a cluster of seedless NWs (FIG. 8b) further indicate that the metallic Zn was removed. XPS analysis was carried before and after the purification step and is shown in FIG. 8c. Prior to purification, the powder shows a peak for Li 1 s at around 56.5 eV where the shift to a higher binding energy (B.E.) compared to metallic lithium (55 eV) indicates that it is present in the form of Li₂O. [27, 28] This Li₂O forms as a by-product in the reduction process as LiBH₄ converts the ZnO to Zn. The absence of a Li 1 s after the purification step suggests that the Li₂O was also removed. The NWs were separated from the acidified IPA by centrifugation and removing the supernatant. The final NW powder retrieved (FIG. 8d) has an orange appearance, characteristic of nanostructured Si.

A standard reaction, whereby a single round of PS and LiBH₄ are added to a reaction yields around 40 mg of NWs, this can be increased by replenishing the consumed PS, LiBH₄ and ZnO during the reaction in series of injection rounds. Up to 5 rounds were injected sequentially in a single reaction allowing for NW yields of up to 200 mg per reaction, resulting in a high growth density of up to 25 mg of NWs per ml of squalane without a diminishing return.

### Equivalents

The foregoing description details presently preferred embodiments of the present invention. Numerous modifications and variations in practice thereof are expected to occur to those skilled in the art upon consideration of these descriptions. Those modifications and variations are intended to be encompassed within the claims appended hereto.

1. A solution-based method for synthesizing a silicon and/or germanium nanowire, said method comprising the steps of:
combining a metal oxide, a reducing agent, and a silicon and/or germanium precursor in liquid media to synthesize the silicon and/or germanium nanowire,
wherein the metal oxide is reduced by the reducing agent to generate a metal catalyst in situ, and the catalyst reacts with the material released from the precursor to synthesize the nanowire, and wherein the metal oxide is a solid.

2. The solution-based method of claim 1, wherein the metal oxide and the precursor are combined prior to adding the reducing agent to the combination.

3. The solution-based method of claim 1, wherein the metal oxide is selected from the group comprising zinc oxide, iron oxide, magnesium oxide, scandium oxide, titanium oxide, manganese oxide, vanadium oxide, chromium oxide, cobalt oxide, and nickel oxide.

4. The solution-based method of claim 1, wherein the metal oxide is zinc oxide (ZnO).

5. The solution-based method of claim 1, wherein the reducing agent is selected from the group comprising lithium aluminium hydride, sodium borohydride, lithium, lithium tetrahydridoaluminate, lithium tri-tert-butoxyaluminum hydride and lithium triethylborohydride and lithium borohydride (LiBH4)

6. (canceled)

7. (canceled)

8. The solution-based method of claim 1, wherein the metal oxide is in the form of a pellet, a powder, or a thin sheet.

9. The solution-based method of any one of the preceding claims claim 1, wherein the precursor is a silicon precursor.

10. The solution-based method of claim 1, wherein the precursor is phenylsilane.

11. The solution-based method of claim 1, wherein the precursor is a germanium precursor.

12. The solution-based method of claim 1, wherein the precursor is a germanium precursor selected from the group consisting of phenylgermane, diphenylgermane, triphenylgermane and GeX4, (X=Cl, Br, I).

13. The solution-based method of any one of the preceding claims claim 1, wherein the metal oxide, the reducing agent, and the silicon and/or germanium precursor are combined in the presence of a solvent.

14. The solution-based method of claim 1, wherein the metal oxide, the reducing agent, and the silicon and/or germanium precursor are combined in the presence of a solvent and wherein the solvent is a refluxing solvent under reflux conditions.

15. The solution-based method of claim 1, wherein the metal oxide, the reducing agent and the silicon and/or germanium precursor are combined in the presence of a solvent and wherein the solvent is selected from the group consisting of squalane, ocadecene and ethylene glycol.

16. The solution-based method of claim 1, wherein the method is conducted in a single chamber.

17. The solution-based method of claim 1, wherein the metal oxide, the reducing agent and the silicon and/or germanium precursor are combined in the presence of a reflux solvent under a reaction temperature of from 370° C. to 490° C.

18. (canceled)

19. The solution-based method of claim 1, further comprising a step of recovering the nanowire.

20. The solution-based method of claim 1, conducted at atmospheric pressure.

21. The solution-based method of claim 1, wherein the method further comprises a step of providing a constant flow of inert argon gas.

22. A silicon and/or germanium nanowire produced by the method of claim 1.

23. (canceled)
